(19) United States
(12) Patent Application Publication
(10) Pub. No.: US 2026/0231807 A1
(43) Pub. Date: Aug. 6, 2026

(54) INTERCONNECT WITH LOW-TEMPERATURE SOLDER CAP

(71) Applicant: Intel Corporation, Santa Clara, CA (US)

(72) Inventors: Kartik Srinivasan, Gilbert, AZ (US); Mihir Oka, Gilbert, AZ (US); Shripad Gokhale, Gilbert, AZ (US); Edvin Cetegen, Chandler, AZ (US); Wei Tan, Chandler, AZ (US); Steve Cho, Chandler, AZ (US); Jonathan Atkins, Phoenix, AZ (US); Rui Zhang, Chandler, AZ (US); Mine Kaya, Scottsdale, AZ (US)

(73) Assignee: Intel Corporation, Santa Clara, CA (US)

(21) Appl. No.: 19/046,811

(22) Filed: Feb. 6, 2025

(51) Int. Cl. H01L 23/00

(52) U.S. Cl. CPC H10W 72/20; H10W 72/072; H10W 72/07232; H10W 72/07255; H10W 72/222; H10W 72/241; H10W 72/252; H10W 72/2524; H10W 72/257; H10W 90/724

(57) ABSTRACT

A low-temperature solder (LTS) cap on solder bumps on a substrate and/or solder bumps on a die may improve head-and-pillow open defects. In some examples, the LTS cap melts earlier than the substrate-side or die-side solder during a TCB process, creating a capillary bridge of molten LTS between the die-side solder and substrate-side solder. In one such example, the molten LTS capillary bridge connecting the die-side and substrate-side bumps may improve the heat transfer to the substrate-side solder and significantly reduce or eliminate head-and-pillow open defects.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes. Some components in a package or assembly may be coupled with one another using solder. The type of solder used may depend on factors such as the location of the interconnect and the components in the assembly. For example, low-temperature solder (LTS) may be used in assemblies with temperature-sensitive components; however, interconnects formed with LTS may have reduced reliability compared to interconnects formed with solder that melts at higher temperatures.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic cross-sectional view of an example microelectronic assembly according to some embodiments of the present disclosure.

FIG. 2 illustrates a cross-sectional view of an example of a microelectronic assembly with interconnects fabricated with low-temperature solder caps, in accordance with examples described herein.

FIGS. 3 and 4 are flow diagrams of examples of methods for fabricating microelectronic assemblies with interconnects using low-temperature solder caps, in accordance with some embodiments.

FIGS. 5A-5D provide cross-sectional side views at various stages in the fabrication of an example microelectronic assembly according to the methods of FIGS. 3 and 4, in accordance with some embodiments.

FIGS. 6-10 illustrate cross-sectional views of examples of microelectronic assemblies with low-temperature solder caps prior to bonding, in accordance with examples described herein.

FIG. 11 is a top view of a wafer and dies that may include any of the IC structures disclosed herein, in accordance with any of the embodiments disclosed herein.

FIG. 12 is a side, cross-sectional view of an IC package that may include an assembly or any of the IC structures disclosed herein, in accordance with various embodiments.

FIG. 13 is a side, cross-sectional view of an IC device assembly that may include an assembly or any of the IC structures disclosed herein, in accordance with any of the embodiments disclosed herein.

FIG. 14 is a block diagram of an example electrical device that may include an assembly or any of the IC structures disclosed herein, in accordance with any of the embodiments disclosed herein.

### DETAILED DESCRIPTION

Disclosed herein are microelectronic components and microelectronic assemblies having interconnects fabricated with low-temperature solder caps. The systems, methods, and devices of this disclosure each have several innovative aspects, no single one of which is solely responsible for all desirable attributes disclosed herein. Details of one or more implementations of the subject matter described in this specification are set forth in the description below and the accompanying drawings.

Advanced packaging architectures are evolving rapidly to meet the demands of modern semiconductor devices, with a focus on reducing the interconnect pitch between components, such as between integrated circuit (IC) dies and a substrate. For example, there is a drive towards reducing the pitch of interconnects between an IC die and an embedded bridge in a substrate to enable higher bandwidth and lower latency.

Conventionally, for larger pitch interconnects in which solder is used, solder balls may be provided on the face of only one of the microelectronic components to be bonded (e.g., either on a die or a substrate). However, as feature sizes and interconnect pitches shrink, there may be insufficient space for the solder bumps on only one side of a bonding interface. Therefore, in some examples, solder may be provided on both sides of a bonding interface. For example, an array of solder bumps may be provided on a face of a die, and a corresponding array of solder bumps that is substantially aligned with the array of solder bumps on the die face may be provided on a face of a substrate. The die and substrate (or another two microelectronic components) may then be bonded together, e.g., with a thermocompression bonding process that causes the solder bumps on the die and the substrate to be bonded together.

Although providing solder on both the die side and substrate side can enable further interconnect pitch scaling, such bonding processes can introduce new challenges, such as the occurrence of head-and-pillow open defects. Head-and-pillow open defects may be especially prevalent when using thermocompression bonding for assembly (also known as thermal compression bonding (TCB)). In a typical thermocompression bonding process, heat is typically applied from one side (e.g., the die side), resulting in the die-side solder reaching a higher temperature than the substrate-side solder during the process. The colder temperature of the substrate-side solder may prevent good wetting and merging of the two solder balls, resulting in a head-and-pillow defect. The term head-and-pillow defect refers to the appearance of a defective solder joint in which the two distinct conductive features (in this case, the two solder balls) make contact with one another without melting to form a uniform solder joint. A head-and-pillow defect typically results in an unstable and open solder joint that may be susceptible to failure during thermal cycling or mechanical stress. One way to prevent head-and-pillow open defects is to increase the peak temperature during the TCB process. However, increasing the peak temperature during the TCB process can reduce yield and can be problematic for finer pitches and larger die sizes. Another technique for preventing head-and-pillow open defects is to use a mass reflow process instead of TCB. However, the use of a mass reflow process may be limited to assemblies that include a thick die and wider bump pitches due to the risk of die warpage during the mass reflow process.

According to examples described herein, providing a layer of low-temperature solder (LTS) over non-LTS bumps on one or both sides (e.g., on the die face and/or on the substrate face) may enable the prevention of head-and-pillow open defects during the fabrication of interconnects with tight pitches. In one example, a first solder material may be plated on conductive contacts (e.g., pads) on a face of a microelectronic component (e.g., die or substrate). A second solder material (e.g., a low-temperature eutectic solder material) may be plated on the first solder material, where the second solder material has a lower melting point than the first solder material. In one such example, the portions of solder have substantially straight/non-rounded sides in a cross-section (e.g., the solder bump and cap have not gone through a reflow process).

In one example, The LTS cap will melt earlier than the non-LTS bumps on the substrate and die during a TCB process, which may create a capillary bridge of molten LTS between the die-side solder and substrate-side solder. The molten LTS capillary bridge connecting the die-side solder bumps and substrate-side solder bumps may significantly improve the heat transfer to the substrate-side solder and may significantly reduce or eliminate head-and-pillow open defects. In one example, a microelectronic assembly fabricated using such a low-temperature solder cap may include a substrate, a die over and bonded with the substrate, and a plurality of conductive interconnects (e.g., solder joints) between the substrate and the die having a pitch that is smaller than or equal to about 35 microns. In one such example, a conductive interconnect of the plurality of conductive interconnects between the die and substrate includes particles from the LTS (e.g., one or both of indium and bismuth, or other LTS particles).

IC structures, microelectronic components and microelectronic assemblies fabricated with low-temperature solder caps as described herein may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of an IC structure, microelectronic component, or microelectronic assembly fabricated with low-temperature solder caps as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

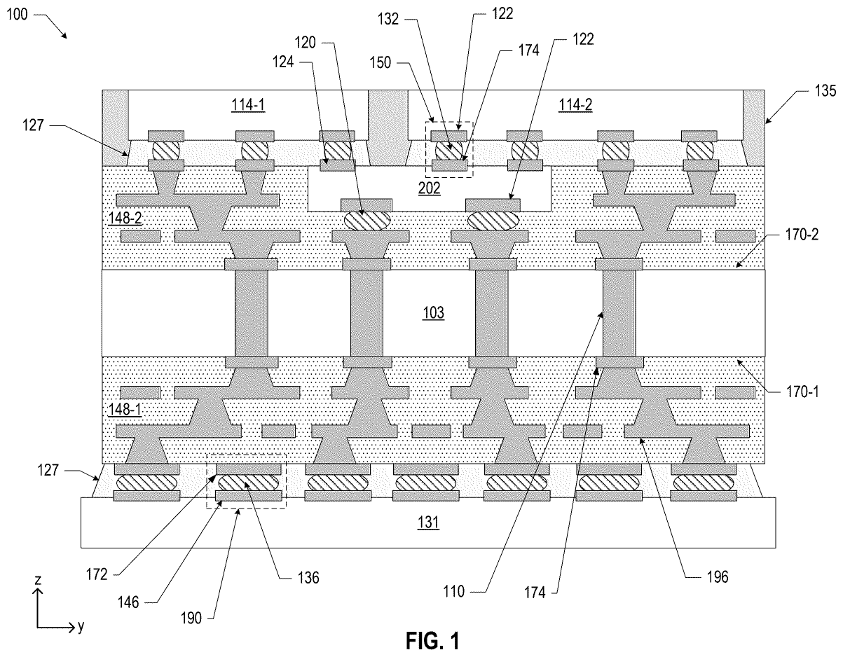

FIG. 1 is a schematic cross-sectional view of an example microelectronic assembly 100 according to some embodiments of the present disclosure. The microelectronic assembly 100 may include a glass core 103. A glass core 103 may further include TGVs 110. TGVs 110 may have any suitable size and shape. A thickness (e.g., z-dimension) of the individual TGVs 110 may be between 50 microns and 2 millimeters (i.e., between 200 microns and 1 millimeter). A diameter (e.g., xy-dimension) of the individual TGVs 110 may be between 5 microns and 100 microns (e.g., between 20 microns and 50 microns). TGVs 110 are shown in FIG. 1 as having straight sides; however, in various embodiments, the TGVs 110 may have sides that taper toward a middle (e.g., have an hourglass shape), and/or have other irregularities depending on the processing conditions for generating TGVs 110. TGVs 110 may be formed using any suitable process, including, for example, via openings may be formed by laser activation and wet etch, laser ablation, or laser drilling, and a conductive material may be deposited in the via openings. TGVs 110 may be formed of any suitable conductive material, such as copper, silver, nickel, gold, aluminum, or other metals or alloys. In some embodiments, a pitch of the TGVs 110 may be between 25 microns and 200 microns (e.g., between 75 microns and 150 microns).

A material of the glass core 103 may include glass, such as bulk transparent glass, and also may be referred to herein as “a glass layer.” As used herein, the term “core” refers to a structure (e.g., a portion of a glass layer) of any glass material such as quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass. In particular, the glass core 103 may be bulk glass or a solid volume/layer of glass, as opposed to, e.g., materials that may include particles of glass, such as glass fiber reinforced polymers. Such glass materials are typically non-crystalline, often transparent, amorphous solids. In some embodiments, the glass core 103 may be an amorphous solid glass layer. In some embodiments, the glass core 103 may include silicon and oxygen, as well as any one or more of aluminum, boron, magnesium, calcium, barium, tin, sodium, potassium, strontium, phosphorus, zirconium, lithium, titanium, and zinc. In some embodiments, the glass core 103 may include a material, e.g., any of the materials described above, with a weight percentage of silicon being at least about 0.5%, e.g., between about 0.5% and 50%, between about 1% and 48%, or at least about 23%. For example, if the glass core 103 is fused silica, the weight percentage of silicon may be about 47%. In some embodiments, the glass core 103 may include at least 23% silicon and/or at least 26% oxygen by weight, and, in some further embodiments, the glass core 103 may further include at least 5% aluminum by weight. In some embodiments, the glass core 103 may include any of the materials described above and may further include one or more additives such as Al2O3, B2O3, MgO, CaO, SrO, BaO, SnO2, Na2O, K2O, SrO, P2O3, ZrO2, Li2O, Ti, and Zn. In some embodiments, the glass core 103 may be a layer of glass that does not include an organic adhesive or an organic material. The glass core 103 may be distinguished from, for example, the “prepreg” or “RF4” core of a printed circuit board (PCB) substrate which typically includes glass fibers embedded in a resinous organic material such as an epoxy. In some embodiments, a cross-section of the glass core 103 in an xz plane, an yz plane, and/or an xy plane of an example coordinate system, shown in FIG. 1, may be substantially rectangular.

The microelectronic assembly 100 may further include a first substrate 148-1 at the first surface 170-1 of the glass core 103 and a second substrate 148-2 at the second surface 170-2 of the glass core 103. The first and second substrates 148-1, 148-2 may include conductive pathways 196 (e.g., including conductive traces and/or conductive vias, as shown) through a dielectric material. The substrates 148-1, 148-2 may include a set of first conductive contacts 172 at the bottom surface of the substrate 148-1, 148-2 and a set of second conductive contacts 174 at the top surface of the substrate 148-1, 148-2, where the conductive pathways 196 electrically couple individual ones of the first and second conductive contacts 172, 174. In some embodiments, conductive contacts 174, 172 at respective first and second surfaces 170-1, 170-2 of the core 103 may be omitted.

The first and second substrates 148-1, 148-2 may be manufactured using any suitable technique, such as a semi-additive process, a subtractive etching technique, or other conventional substrate package techniques. In some embodiments, a dielectric material of the substrates 148-1, 148-2 may include bismaleimide triazine (BT) resin, polyimide materials, epoxy materials (e.g., glass reinforced epoxy matrix materials, epoxy buildup films, or the like), mold materials, oxide-based materials (e.g., silicon dioxide or spin on oxide), or low-k and ultra low-k dielectric (e.g., carbon-doped dielectrics, fluorine-doped dielectrics, porous dielectrics, and organic polymeric dielectrics). The TGVs 110 in the glass core 103 may electrically couple the first and second substrates 148-1, 148-2. As used herein, the glass core 103 with the second substrate 148-2 and/or the first substrate 148-1 may be referred to as a package substrate. TGVs 110 in glass core 103 may enable power, ground and signal connectivity to components located on either side of the glass core 103, for example, between dies 114-1, 114-2 and a circuit board 131.

The microelectronic assembly 100 may further include die 114-1 and die 114-2 electrically coupled to a top surface of the second substrate 148-2 by interconnects 150. In particular, conductive contacts 122 on a bottom surface of die 114-1, 114-2 may be electrically and mechanically coupled to conductive contacts 174 at a top surface of the second substrate 148-2 by interconnects 150.

Interconnects 150 disclosed herein may take any suitable form. In some embodiments, a set of interconnects 150 may include solder 132 (e.g., solder bumps or balls that are subject to a thermal reflow to form the interconnects 150). Interconnects 150 that include solder may include any appropriate solder material, such as eutectic tin/bismuth, eutectic tin/indium, eutectic tin/bismuth/indium, lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, and/or other alloys. In some embodiments, a set of interconnects 150 may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression. In some embodiments, interconnects 150 disclosed herein may have a pitch that is smaller than about 35 microns, e.g., in a range between about 18 microns and 35 microns. Although FIG. 1 shows dies 114-1, 114-2 electrically coupled to substrate 148-2 by interconnects 150, dies 114-1, 114-2 may be electrically coupled by any suitable interconnects.

The dies 114-1, 114-2 disclosed herein may include an insulating material (e.g., a dielectric material formed in multiple layers, as known in the art) and multiple conductive pathways formed through the insulating material. In some embodiments, the insulating material of a die 114-1, 114-2 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114-1, 114-2 may include a semiconductor material, such as silicon, germanium, or a III-V material (e.g., gallium nitride), and one or more additional materials. For example, an insulating material may include silicon oxide or silicon nitride. The conductive pathways in a die 114-1, 114-2 may include conductive traces and/or conductive vias, and may connect any of the conductive contacts in the die 114-1, 114-2 in any suitable manner (e.g., connecting multiple conductive contacts on a same surface or on different surfaces of the die 114-1, 114-2). The conductive pathways in the dies 114-1, 114-2 may be bordered by liner materials, such as adhesion liners and/or barrier liners, as suitable. In some embodiments, the die 114-1, 114-2 is a wafer. In some embodiments, the die 114-1, 114-2 is a monolithic silicon, a fan-out or fan-in package die, or a die stack (e.g., wafer stacked, die stacked, or multi-layer die stacked). In various embodiments, die 114-1, 114-2 may include, or be a part of, one or more of a central processing unit (CPU), a memory device (e.g., a high-bandwidth memory device), a logic circuit, input/output circuitry, a transceiver such as a field programmable gate array transceiver, a gate array logic such as a field programmable gate array logic, of a power delivery circuitry, a III-V or a III-N device such as a III-N or III-N amplifier (e.g., GaN amplifier), Peripheral Component Interconnect Express (PCIe) circuitry, Double Data Rate (DDR) transfer circuitry, or other electronic components known in the art. In some embodiments, die 114-1 and die 114-2 may include different functionalities. As used herein, the term “functionality” with reference to a die refers to one or more functions (e.g., capability, task, operation, action, instruction execution, etc.) that the die in question can perform. For example, die 114-1 may be a CPU and die 114-2 may be a Graphics Processing Unit (GPU) or memory. In other embodiments, die 114-1 and die 114-2 may include the same or similar functionalities. For example, die 114-1 and die 114-2 may each include memory.

The microelectronic assembly 100 of FIG. 1 may also include a bridge die 202. A bridge die 202 may be at least partially within (e.g., embedded in) a dielectric material of the second substrate 148-2 (e.g., at least partially nested in a cavity). The bridge die 202 may be electrically coupled to dies 114-1 and die 114-2 by interconnects 150. In particular, conductive contacts 122 on the bottom surface of dies 114-1, 114-2 may be electrically and mechanically coupled to the conductive contacts 124 on the top surface of the bridge die 202 by interconnects 150. A bridge die 202 may be electrically coupled to conductive pathways 196 in the second substrate 148-2 by interconnects 120. In some embodiments, as shown, interconnects 120 may include solder. In some examples, a bridge die 202 may comprise appropriate circuitry on/in a semiconductor substrate to connect at silicon-interconnect speeds with a small footprint. In some embodiments, a bridge die 202 may comprise active components, such as transistors and diodes in addition to bridge/interconnect circuitry including metallization traces, vias and passive components for enabling electrical coupling between two ICs; in other embodiments, a bridge die 202 may include bridge circuitry including metallization traces, vias and passive components for enabling electrical coupling between die 114-1 and die 114-2, and may not include active components. In some embodiments, a bridge die 202 may be omitted.

The microelectronic assembly 100 of FIG. 1 may also include an insulating material 135 that encapsulates the dies 114-1 and 114-2 (e.g., on and around the dies 114-1 and 114-2 and interconnects 150). The insulating material 135 may extend from a top surface of the second substrate 148-2 to a top surface of the dies 114-1 and 114-2. In some embodiments, the insulating material 135 may be a mold material, such as an organic polymer with inorganic silicon oxide or aluminum oxide particles, a resin material, or an epoxy material. In some embodiments (not shown) other components, such as heat sinks may be coupled to microelectronic assembly 100 based on particular needs.

The microelectronic assembly 100 of FIG. 1 may also include an underfill material 127. In some embodiments, the underfill material 127 may extend between the dies 114-1, 114-2 and the second substrate 148-2 around the associated interconnects 150. In some embodiments, the underfill material 127 may be between the bottom surface of the bridge die 202 and the second substrate 148-2 (not shown). The underfill material 127 may be an insulating material, such as an appropriate epoxy material. In some embodiments, the underfill material 127 may include a capillary underfill, non-conductive film (NCF), or molded underfill. In some embodiments, the underfill material 127 may include an epoxy flux that assists with soldering the dies 114-1, 114-2 to the second substrate 148-2 when forming the interconnects 150, and then polymerizes and encapsulates the interconnects 150. The underfill process may include dispensing underfill material in liquid form, allowing the material to flow and fill the interstitial gaps around interconnects 150, and subjecting the assembly to a curing process, such as baking, to solidify the material. In some embodiments, an underfill material 127 may be omitted. Although FIG. 1 shows two separate underfill material 127 portions under the die 114-1 and die 114-2, the underfill material 127 may be a single underfill material 127 under die 114-1 and die 114-2. The underfill material 127 may be selected to have a coefficient of thermal expansion (CTE) that may mitigate or minimize the stress between dies 114-1, 114-2 and the second substrate 148-2 arising from uneven thermal expansion in the microelectronic assembly 100. In some embodiments, the CTE of the underfill material 127 may have a value that is intermediate to the CTE of the second substrate 148-2 (e.g., the CTE of the dielectric material of the substrates 148-1, 148-2) and a CTE of the insulating material of dies 114-1 and 114-2.

The microelectronic assembly 100 of FIG. 1 may also include a circuit board 131. In particular, conductive contacts 172 on a bottom surface of the first substrate 148-1 may be electrically coupled to conductive contacts 146 on a top surface of circuit board 131 by interconnects 190. Interconnects 190 disclosed herein may take any suitable form, including solder balls for a ball grid array arrangement, pins in a pin grid array arrangement or lands in a land grid array arrangement, or any of the forms described above with reference to interconnects 150. As shown in FIG. 1, in some embodiments, a set of interconnects 190 may include solder 136 (e.g., solder bumps or balls that are subject to a thermal reflow to form the interconnects 190). In some embodiments, the interconnects 190 disclosed herein may have a pitch between about 50 microns and 300 microns. In some embodiments, an underfill material 127 may extend between the first substrate 148-1 and the circuit board 131 around the associated interconnects 190. The circuit board 131 may be a motherboard, for example, and may have other components attached to it. The circuit board may include conductive pathways and other conductive contacts for routing power, ground, and signals through the circuit board, as known in the art. In some embodiments, the interconnects 190 may not couple to a circuit board 131, but may instead couple to another IC package, an interposer, or any other suitable component.

In some embodiments, one or more levels of solder resist (e.g., epoxy liquid, liquid photoimageable dielectrics, dry film photoimageable dielectrics, acrylics, solvents) may be provided in an IC package described herein and may not be labeled or shown to avoid cluttering the drawings. Solder resist may be a liquid or dry film material including photoimageable dielectric materials. In some embodiments, solder resist may be non-photoimageable.

The interconnects between various microelectronic components of the assembly 100 may be fabricated with low-temperature solder caps, in accordance with examples described herein. For example, the interconnects 150 between and coupled with the die 114-2 and the bridge die 202, which may have a relatively small pitch, may be examples of conductive interconnects fabricated with low-temperature solder caps. The interconnects 190 may also, or alternatively, be examples of conductive interconnects fabricated with low-temperature solder caps. Other interconnects in a microelectronic assembly other than those explicitly shown in FIG. 1 may also, or alternatively, be fabricated using low-temperature solder caps. According to examples, conductive interconnects fabricated with low-temperature solder caps include particles of the low-temperature solder material (e.g., LTS eutectic phase) in the interconnect.

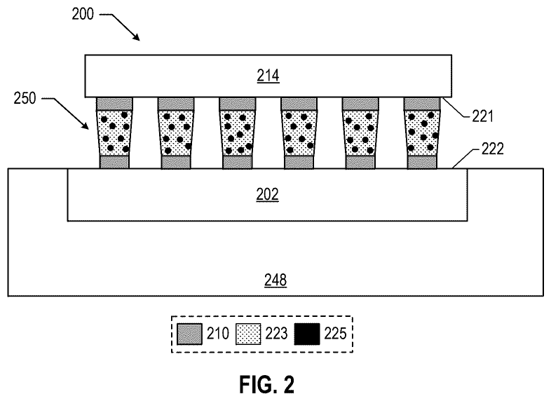

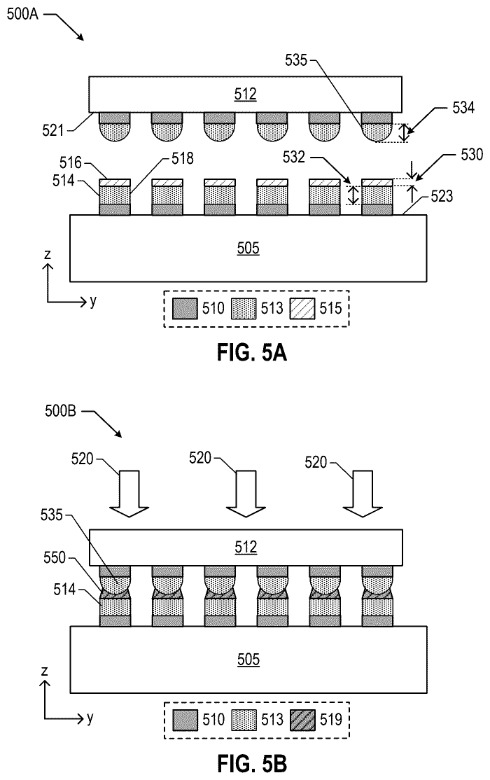

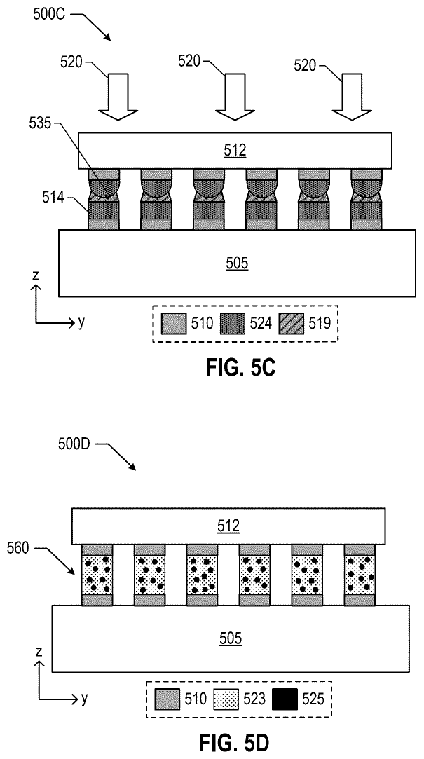

FIG. 2 illustrates a cross-sectional view of an example of a microelectronic assembly 200 with interconnects fabricated with low-temperature solder caps, in accordance with examples described herein. A number of elements referred to in the description of FIG. 2 as well as FIGS. 5A-5D and 6-9 with reference numerals are illustrated in these drawings with different patterns, with a legend showing the correspondence between the reference numerals and patterns being provided at the bottom of each drawing page containing FIGS. 2, 5A-5D, and 6-9. For example, the legend illustrates that FIG. 2 uses different patterns to show a conductive contacts 210 and non-LTS 223, and so on.

The microelectronic assembly 200 includes a substrate 248 with an embedded bridge die 202. An IC die 214 is over and coupled with the substrate 248, and over and coupled with the bridge die 202 embedded in the substrate 248. The microelectronic assembly 200 includes a plurality of conductive interconnects 250, between and coupled with the die 214 and the substrate 248. The conductive interconnects 250 include a solder joint of one or more solder materials between conductive contacts 210 (e.g., conductive pads). In some examples, the solder joints may have a width that is smaller than solder joints of a large ball grid array (e.g., smaller than the width of the solder 135 of the interconnects 190 shown in FIG. 1), where the width is a dimension of the solder joints in a plane substantially parallel with the substrate 248. In one example, the solder joints may have a width in a range of about 10 to 25 microns. In other examples, the solder joints may have a width that is smaller than 10 microns or greater than 25 microns. The conductive contacts 210 may include any suitable conductive material, such as copper and/or another conductive material. Although the conductive contacts 210 are shown on the face 221 of the die 214 and on the face 222 of the substrate 248, in other examples, conductive contacts 210 may be partially or fully recessed in the die 214 and/or in the substrate 248.

The conductive interconnects 250 include a non-LTS 223 and low-temperature solder particles 225 (which in some examples may be referred to as eutectic LTS phase). In one such example, the low-temperature solder particles may be SnBi LTS eutectic Bi phase. In some examples, the low-temperature solder particles 225 may be areas or regions of the solidified low-temperature solder in the non-LTS 223 (e.g., in a cross section of a conductive interconnect 250, as shown in FIG. 2). Although FIG. 2 depicts low-temperature solder particles 225 as having a round shape and uniform size for ease of illustration, low-temperature solder particles may have a variety of shapes and/or sizes within the non-LTS 223. In some examples, the low-temperature solder particles 225 may be present throughout the cross-section. In one example, the low-temperature solder particles are substantially uniformly distributed throughout the non-LTS such that the conductive interconnect 250 includes low-temperature solder particles 225 at both ends (e.g., proximate to the conductive contacts on both the faces 221 and 222) and in a region between the ends of the conductive interconnect 250. In one example, an LTS may be a solder material with a melting point in a range of about 120-140 degrees C. A non-LTS may be a solder material with a melting point in a range of about 220-230 degrees C. Thus, in some examples, the LTS and non-LTS may have a difference in melting point of about 80 to 110 degrees C. In some examples, the LTS is a eutectic LTS with a relatively low melting point, and the non-LTS may be a non-eutectic solder material with a melting point range that is greater than the melting point of the eutectic LTS.

The conductive interconnects 250 may have a pitch that is smaller than or equal to about 35 microns. Thus, in some examples, the interconnects 250 may be formed using a fabrication technique in which solder bumps are provided on both the die side and the substrate side (e.g., solder may be provided on the face 221 of the die 214 and the face 222 of the substrate 248 or bridge die 202), and where a low-temperature solder cap is provided on one or more of the solder bumps. As mentioned above, particles from the low-temperature solder cap may be present throughout the resulting solder joint. For example, where the low-temperature solder includes indium and/or bismuth (e.g., SnBi, SnIn, or SnBiIn), the resulting interconnects may include bismuth and/or indium particles.

The percentage of low-temperature solder in the conductive interconnects 250 may depend on a variety of factors and may impact the performance and reliability of the interconnects. In one example, the conductive interconnects may be formed with solder bumps of a first solder material (e.g., a non-LTS such as SnAgCu or another suitable solder material) on both the die side and the substrate side, and a LTS cap on at least some solder bumps on the die side or the substrate side. In one such example, the resulting solder joint may include SnAgCu solder with a few percent (e.g., in a cross-sectional area or volume) of bismuth or indium, or a higher percent of bismuth or indium.

FIG. 2 illustrates an example in which the interconnects 250 include a non-LTS 223 and low-temperature particles 225. In one such example, a conductive interconnect 250 may include about 1-5% bismuth in a non-LTS in a cross-sectional area of a solder joint portion of the conductive interconnect 250. In one such example, the conductive interconnect 250 may include dopants such as copper, nickel, and germanium, which may improve reliability of the conductive interconnect. In another example, a conductive interconnect 250 may include about 1-2% or about 1-15% indium in a non-LTS in a cross-sectional area of a solder joint portion of the conductive interconnect 250. In other examples, a conductive interconnect may include more than a few percent of eutectic LTS phase. In one example, a conductive interconnect 250 may include about 30-40% bismuth in a non-LTS in a cross-sectional area of a solder joint portion of the conductive interconnect 250. In another example, a conductive interconnect 250 may include about 15-25% indium in a non-LTS in a cross-sectional area of a solder joint portion of the conductive interconnect 250. In some examples, the LTS particles 225 may be substantially uniformly distributed within the solder joint.

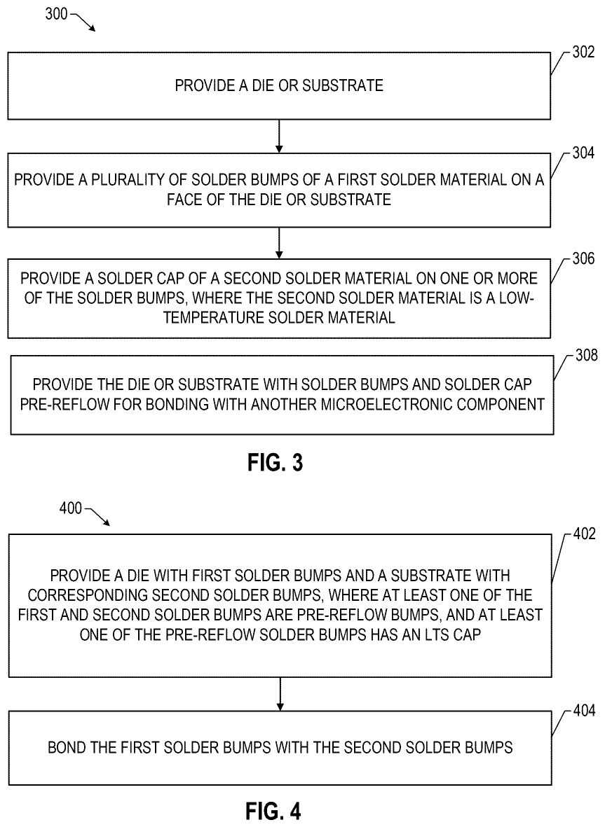

FIGS. 3 and 4 are flow diagrams of example methods 300 and 400 for fabricating microelectronic assemblies using LTS caps. The method 300 of FIG. 3 is a method of fabricating a microelectronic component or subassembly with solder bumps and LTS caps for bonding with another microelectronic component, as described herein. The method 400 of FIG. 4 is a method of fabricating a microelectronic assembly, including bonding the microelectronic component with the LTS caps with another microelectronic component. FIGS. 5A-5D provide cross-sectional views along the y-z axis at various stages in the fabrication of an example microelectronic assembly according to the methods of FIGS. 3 and 4, in accordance with some embodiments.

Although the operations of the methods of FIGS. 3 and 4 are illustrated once each and in a particular order, the operations may be performed in any suitable order and repeated as desired. For example, one or more operations may be performed in parallel to fabricate multiple IC structures or microelectronic assemblies including LTS caps substantially simultaneously. In another example, the operations may be performed in a different order to reflect the structure in which LTS caps will be implemented.

In addition, the example fabricating methods of FIGS. 3 and 4 may include other operations not specifically shown in FIGS. 3 and 4, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the methods of FIGS. 3 and 4 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 3, the method 300 begins with a process 302 of providing a die or substrate. For example, referring to FIG. 5A, providing a die or substrate may involve providing the substrate 505. Referring to FIG. 1, providing a die or substrate may refer to providing the IC die 114-1, the IC die 114-2, the substrate 148-2, a subassembly including the substrate 148-2, the substrate 148-1, and the glass core 103, or providing any other microelectronic component to be bonded with another microelectronic component using an LTS cap as described herein.

The method 300 continues with a process 304 of providing solder bumps of a first solder material on a face of the die or substrate. For example, referring to FIG. 5A, providing solder bumps of a first solder material may involve providing a portion of a first solder material 513 on an individual conductive contact 510 to form the solder bumps 514 of the first solder material 513. Providing the first solder material 513 may involve plating the first solder material 513 on conductive contacts 510 on the face 523 of the substrate 505. The first solder material 513 may be a non-low-temperature solder material. In one example, the first solder material 513 may be a non-eutectic solder material. In one example, the first solder material may be any suitable non-LTS, such as SnAgCu, or another suitable solder material. In the example illustrated in FIG. 5A, the solder bumps 514 are provided without undergoing a reflow process, and therefore have a non-round cross-sectional shape (e.g., the pre-reflow solder bumps 514 have substantially straight sides 518 in a cross-sectional in a plane substantially orthogonal to the substrate 505). In other examples, the solder bumps provided in the process 304 may be provided on a die, such as the die 512 of FIG. 5A.

The method 300 continues with a process 306 of providing a solder cap of a second solder material on one or more of the solder bumps, where the second solder material is a low-temperature solder material. For example, referring to FIG. 5A, providing the solder cap may involve providing a portion of a second solder material 515 on the portion of the first solder material 513 to form a solder cap 516 of a second solder material 515. Providing the second solder material 515 may involve plating the second solder material 515 onto the first solder material 513. In some examples, plating the second solder material 515 may involve multiple plating processes (e.g., separate deposition of tin and bismuth to provide a solder cap of SnBi). The second solder material 515 may be a low-temperature solder material, such as the example LTS materials described above. For example, the first solder material 513 may have a first melting point (or melting point range), and the second solder material 515 may have a second melting point that is lower than the first melting point (or melting point range). In some examples, the second solder material 515 is a eutectic solder material (e.g., SnBi58 eutectic, SnIn50 eutectic, or another eutectic solder material). In some examples, the second solder material is a hypoeutectic solder material (e.g., hypoeutectic SnBi or another hypoeutectic solder material). In some examples, the second solder material is a gamma phase solder material (e.g., gamma phase SnIn or another gamma phase solder material).

The thickness 530 of the LTS cap 516 may vary depending on the desired percentage of LTS particles in the resulting solder joint and the thickness 532 of the solder bump 514. In some examples, in some examples, the ratio of the thickness 532 of the solder bump 514 to the thickness 530 of the solder cap is in a range of about 1:30 to 1:1, or about 1:30 to 1:6, where the thicknesses 530 and 532 are dimensions of the LTS cap 516 and the solder bump 514, respectively, in a plane substantially orthogonal to the substrate 505 (e.g., along the z-axis as shown in FIG. 5A). In one such example, if the thickness 532 of the solder bump 514 is about 10 microns and the thickness 534 of a solder bump 535 on the die side is about 10 microns (e.g., for a total of about 20 microns of thickness of the first solder material 513), the thickness 530 of the solder cap 516 may be in a range of about 0.3 microns to 2 microns (e.g., for a relatively thin LTS cap), in a range of about 10 to 14 microns (e.g., for a thicker LTS cap), or any other suitable thickness (e.g., any thickness between about 0.3 microns and 14 microns). In other examples, the thickness 530 may be smaller than 3 microns or greater than 14 microns.

The process continues with a process 308 of providing the die or substrate with the solder bumps and solder cap pre-reflow for bonding with another microelectronic component. For example, FIG. 5A illustrates an example microelectronic assembly 500A in which the substrate 505 is provided with the solder bumps 514 and solder caps 516 for bonding with the die 512 without first undergoing reflow. As a result, the cross-sectional shape of the solder bumps 514 with LTS caps 516 are substantially non-round (e.g., with substantially straight sides 518). In contrast, the solder bumps 535 on the die 512 have undergone reflow, and therefore have a round cross-sectional shape. In one example, providing the substrate 505 with the solder bumps 514 and LTS caps 516 prior to reflow may prevent the second solder material 515 from becoming dispersed in the first solder material 513 of the solder bumps 514 prior to bonding with the die 512.

Turning to FIG. 4, the method 400 begins with a process 402 of providing a die with first solder bumps and a substrate with corresponding second solder bumps, where at least one of the first and second solder bumps have substantially straight sides (e.g., are pre-reflow solder bumps), and at least one of the pre-reflow solder bumps has an LTS cap. The microelectronic assembly 500A of FIG. 5A is an example resulting structure of the process 402. As discussed above with respect to FIG. 3, the substrate 505 is provided with pre-reflow solder bumps 514 and pre-reflow LTS caps 516, which have relatively straight sides 518 instead of rounded sides. In the example illustrated in FIG. 5A, all of the solder bumps 514 on the substrate side are capped with the second solder material 515; however, as described in more detail below, fewer than all the solder bumps 514 may have LTS caps. In the example illustrated in FIG. 5A, the die 512 is provided with solder bumps 535 on conductive contacts 510 on the face 521 of the die 512.

The method 400 continues with a process 404 of bonding the first solder bumps with the second solder bumps. Bonding the first solder bumps with the second solder bumps may involve a thermocompression bonding process to align and bond the die 512 with the substrate 505. In one example, a thermocompression bonding process involves applying heat from the die side of the assembly. The microelectronic assembly 500B of FIG. 5A, the microelectronic assembly 500B of FIG. 5B, and the microelectronic assembly 500C of FIG. 5C, are example microelectronic assemblies at different times in performance of the process 404. Turning first to FIG. 5B, the arrows 520 illustrate heat being applied to the microelectronic assembly 500B from the die side. Initially in the TCB process, the solder material of the LTS cap 516 begins to melt before the solder material of the solder bumps 514 and the solder bumps 535. As a result, a layer 550 of molten low-temperature solder 519 is between the solder bumps 514 and the solder bumps 535. The molten layer 550 of LTS may form a capillary bridge between the solder bumps 514 on the substrate and the solder bumps 535 on the die 512, improving heat transfer from the die side to the substrate side. The improved heat transfer may enable the bumps on both the die side and the substrate side to melt more evenly. For example, FIG. 5C illustrates an example microelectronic assembly 500C in which the both the solder bumps 514 on the substrate 505 and the solder bumps 535 on the die 512 have melted (as shown by the molten non-LTS 524). The enhanced heat transfer enabled by the LTS caps 516 can thus enable the solder balls on both the die side and the substrate side to melt to form solder joints without defects such as head-and-pillow-open defects. FIG. 5D illustrates an example microelectronic assembly 500D with a plurality of solder joints 560. As can be seen in FIG. 5D, after the TCB process, solidified LTS particles 525 may be present in the solder joints 560.

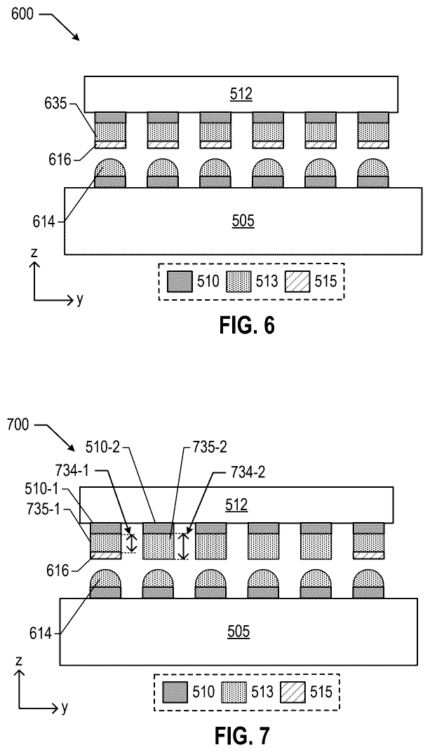

FIGS. 6-9 illustrate cross-sectional views of examples of microelectronic assemblies with low-temperature solder caps prior to bonding, in accordance with examples described herein. FIG. 6 illustrates an example microelectronic assembly 600 in which the LTS caps 616 are provided on the solder bumps 635 on the die side instead of the solder bumps 614 on the substrate side. The LTS caps 616 may be an example of any of the LTS caps discussed above. In the example illustrated in FIG. 6, the die with the solder bumps 635 and LTS caps 616 is provided for bonding with the substrate 505 pre-reflow, and therefore the solder bumps 635 and the LTS caps 616 have a non-round shape.

FIG. 7 illustrates another microelectronic assembly 700 in which the LTS caps 616 are provided on only some of the solder bumps of the die 512. For example, the microelectronic assembly 700 includes a first portion or solder bump 735-1 of the first solder material 513 on a first conductive contact 510-1, and a second portion or solder cap 616 on the solder bump 735-1. A third portion or solder bump 735-2 is on a second conductive contact 510-2 adjacent to the first conductive contact 510-1. As can be seen in FIG. 7, the solder bump 735-2 lacks a solder cap of the second solder material 515. Therefore, in the example illustrated in FIG. 7, the height or thickness 734-2 of the solder bump 735-2 is greater than the height or thickness 734-1 of the solder bump 735-1 (e.g., the thickness 734-2 is about equal to the thickness 734-1 plus the thickness of the cap 616), where the thicknesses 734-1 and 734-2 are dimensions of the solder bumps in a plane substantially orthogonal to the substrate (e.g., along the z-axis as shown in FIG. 7). Therefore, in the example illustrated in FIG. 7, a portion of the first solder material 513 of the solder bump 735-2 is coplanar with both the first solder material 513 of the solder bump 735-1 and the second solder material of the LTS cap 616. In some examples, the solder bumps with the LTS caps (such as the solder bump 735-1) may be closer to an edge of the die 512 and/or closer to a corner of the die 512 than a solder bump without an LTS cap (such as the solder bump 735-2). Providing LTS caps on only some solder bumps may involve an additional plating step in the substrate/die-side plating process; however, providing LTS caps on only some of the solder bumps between the substrate 505 and the die 512 may have the benefit of minimizing reliability risks associated with adding LTS to all the solder joints between the substrate 505 and the die 512, while providing yield margin for head-and-pillow defects in high risk regions (e.g., the edges, corners, or other high risk regions).

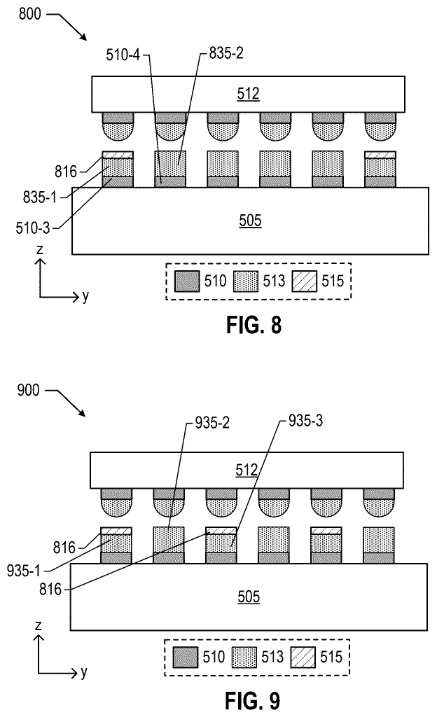

FIG. 8 illustrates another microelectronic assembly 800 in which the LTS caps 816 are provided on only some of the solder bumps of the die substrate 505. Similar to FIG. 7, the microelectronic assembly 800 of FIG. 8 includes a solder bump 835-1 on a conductive contact 510-3, which may be proximate to an edge/and or corner of the substrate 505 (and/or proximate to an edge and/or corner of the die 512 after bonding), and a solder bump 835-2 on a conductive contact 510-4 that is closer to a middle region of the substrate 505 and/or a middle region of the die 512. As can be seen in FIG. 8, an LTS cap 816 is present on the solder bump 835-1 and absent from the solder bump 835-2. Although FIGS. 7 and 8 depict only a single solder bump with a cap near an edge and/or corner, LTS caps may be present on one or multiple solder bumps in a variety of configurations. For example, FIG. 9 illustrates an example microelectronic assembly 900 in which solder bumps with LTS caps are alternated with solder bumps without LTS caps. For example, in the example illustrated in FIG. 9, the solder bump 935-2 without an LTS cap is between the solder bumps 935-1 and 935-3 with LTS caps. In other examples, multiple adjacent solder bumps may have LTS caps, while other solder bumps lack LTS caps. Although the example in FIG. 9 shows the LTS caps on the solder bumps on the substrate-side, a similar configuration of LTS caps may be present on the die side.

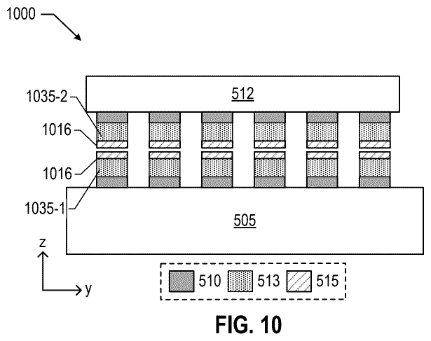

FIG. 10 illustrates another microelectronic assembly 1000 in which the LTS caps 1016 are provided solder bumps on both the substrate side and the die side. For example, an LTS cap 1016 is on the solder bump 1035-1 on a face of the substrate 505, and an LTS cap 1016 is on a corresponding solder bump 1035-2 on a face of the die 512. Although FIG. 10 illustrates an example in which all the solder bumps between the die 512 and the substrate 505 have LTS caps, in other examples, fewer than all the solder bumps between the die 512 and the substrate 505 may have LTS caps.

Accordingly, a low-temperature solder cap may be provided on non-LTS bumps on a substrate or die. In some examples, the thickness of the LTS cap can be modulated to obtain the desired properties for particular products. In some examples, the LTS cap melts earlier than the substrate-side or die-side solder during the TCB process, creating a capillary bridge of molten LTS between the die-side solder and substrate-side solder. The molten LTS capillary bridge connecting the die-side and substrate-side bumps may significantly improve the heat transfer to the substrate-side solder and significantly reduce/eliminate head-and-pillow open defects. In some examples, using an LTS cap in the interconnect can help reduce/eliminate head-and-pillow assembly defects in embedded bridge regions (e.g., EMIB regions), and thus enable scaling of EMIB interconnects finer pitches. Additionally, using an LTS cap in accordance with examples described herein may enable increasing the die size (e.g., larger than reticle die size) while maintaining good yield and competitive assembly costs.

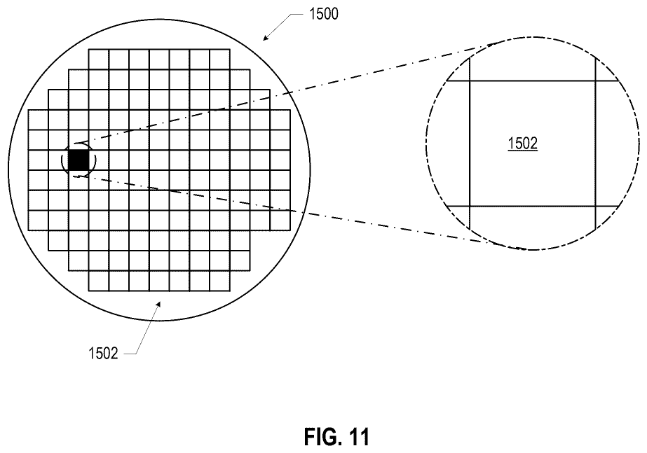

IC structures and microelectronic assemblies fabricated LTS caps in accordance with techniques described herein may be included in any suitable electronic component or electronic device. FIGS. 11-14 illustrate various examples of apparatuses that may include one or more of the IC structures or assemblies fabricated with LTS caps as disclosed herein.

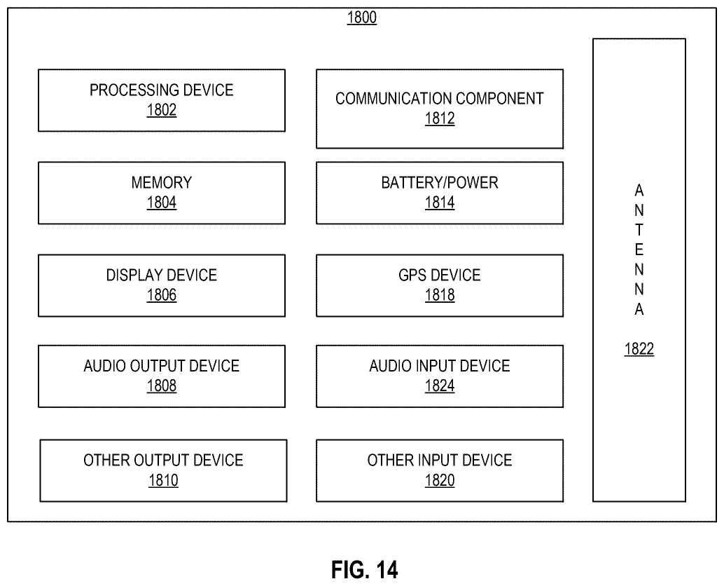

FIG. 11 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 14) or other logic that is configured to store information in the memory devices or execute instructions stored in the memory array.

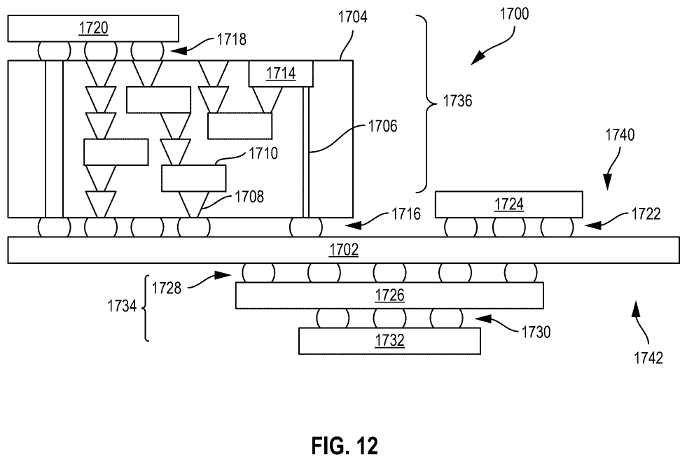

FIG. 12 is a side, cross-sectional view of an example IC package 1650 that may include an assembly or one or more IC structures fabricated using an LTS cap in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 12 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 12 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

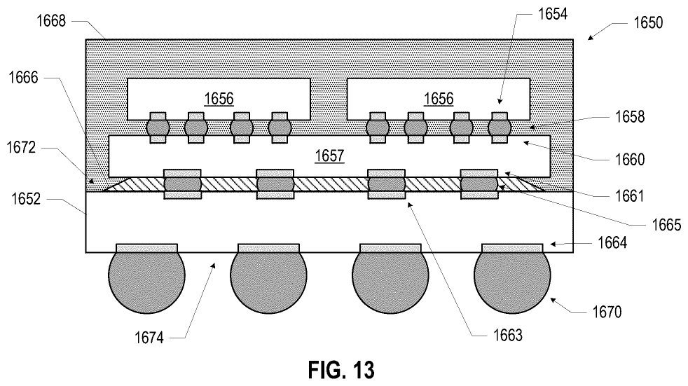

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 12 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 13.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 12 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fan-out (FO) package. Although two dies 1656 are illustrated in the IC package 1650 of FIG. 12, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 13 is a side, cross-sectional view of an IC device assembly 1700 that may include one or more IC packages or other electronic components (e.g., a die) including an assembly or one or more IC structures fabricated using an LTS cap in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 12 (e.g., may include one or more IC structures in accordance with embodiments described herein).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 13 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 13), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 13, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 11), an IC device, or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 13, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 13 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 14 is a block diagram of an example electrical device 1800 that may include an assembly or one or more IC structures fabricated using an LTS cap in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 14 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 14, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded DRAM (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP 2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an apparatus, including a microelectronic component (e.g., die, substrate, e.g., package substrate, etc.), where a face of the microelectronic components includes conductive contacts (e.g., conductive pads); a first portion of a first solder material on an individual conductive contact of the conductive contacts; and a second portion of a second solder material on the first portion, where: the first portion and the second portion have substantially straight sides in a cross-section of the apparatus in a plane substantially orthogonal to the microelectronic component (e.g., the solder has not gone through reflow), the first solder material has a first melting point (or melting point range), and the second solder material has a second melting point that is lower than the first melting point.

Example 2 provides the apparatus of example 1, where: the microelectronic component includes an IC die or a package substrate.

Example 3 provides the apparatus of any one of examples 1-2, where: the microelectronic component includes a package substrate, the package substrate includes an embedded bridge die, and the first portion and the second portion are over and coupled with the embedded bridge die.

Example 4 provides the apparatus of any one of examples 1-3, where the individual contact is a first conductive contact, and where the apparatus further includes a second conductive contact adjacent to the first conductive contact; and a third portion of the first solder material on the second conductive contact, where the first solder material of the third portion is coplanar with the first portion and the second portion (e.g., the second contact has only the first solder and lacks a cap).

Example 5 provides the apparatus of example 4, where: the first portion has a first thickness, where the first thickness is a first dimension of the first portion in a first plane substantially orthogonal to the microelectronic component, the third portion has a second thickness, where the second thickness is a second dimension of the third portion in a second plane substantially orthogonal to the microelectronic component, and the second thickness is greater than the first thickness (e.g., the thickness or height of the non-LTS bump without a cap is greater than the thickness or height of an adjacent non-LTS bump with a LTS cap).

Example 6 provides the apparatus of any one of examples 4-5, where: the first portion is closer to an edge of the microelectronic component than the third portion (e.g., the bump with a cap is closer to the edge of the microelectronic component than the bump without a cap).

Example 7 provides the apparatus of any one of examples 1-6, where: the first portion has a first thickness, where the first thickness is a first dimension of the first portion in a plane substantially orthogonal to the microelectronic component, the second portion has a second thickness, where the second thickness is a second dimension of the second portion in the plane, and a ratio of the first thickness to the second thickness is in a range of about 1:1 to 50:1 (or, e.g., 10:1 to 50:1).

Example 8 provides the apparatus of example 7, where: the second thickness is in a range of about 0.3 to 14 microns.

Example 9 provides the apparatus of any one of examples 1-8, where: the second solder material includes a eutectic solder material including one or both of bismuth and indium (e.g., the second solder may include SnBi, SnIn, or SnBiIn).

Example 10 provides the apparatus of any one of examples 1-9, where: the pitch of the conductive contacts and corresponding solder bumps on the conductive contacts is smaller than or equal to about 35 microns.

Example 11 provides an apparatus, including a microelectronic component; a solder bump on a face of the microelectronic component, where the solder bump includes a first pre-reflow portion of a first solder material; and a solder cap on the solder bump, where: the solder cap includes a second pre-reflow portion of a second solder material, and the second solder material includes a eutectic solder material including tin and one or more of bismuth and indium.

Example 12 provides the apparatus of example 11, where the solder bump is a first solder bump, the solder cap is a first solder cap, and where the apparatus further includes a second solder bump coplanar with the first solder bump, where: the second solder bump includes a third pre-reflow portion of the first solder material, and the second solder bump lacks a second solder cap of the second solder material.

Example 13 provides the apparatus of example 12, where: the third pre-reflow portion of the first solder material is coplanar with the first solder bump and the first solder cap.

Example 14 provides the apparatus of any one of examples 11-13, where: the first solder bump is closer to a corner of the microelectronic component than the second solder bump (e.g., the bump with a cap is closer to the corner of the microelectronic component than the bump without a cap).

Example 15 provides a microelectronic assembly, including a substrate including a first die (e.g., bridge/interconnect die) in a recessed region of the substrate; a second die over and bonded with the second die; and a plurality of conductive interconnects between the first die and the second die, where: a conductive interconnect of the plurality of conductive interconnects includes one or both of indium and bismuth, and a percentage of bismuth or indium in a cross-sectional area of the interconnect is in a range of about 1 to 40 percent.

Example 16 provides the microelectronic assembly of example 15, where: a pitch of the conductive interconnects is smaller than about 35 microns.

Example 17 provides the microelectronic assembly of any one of examples 15-16, where: a percentage of bismuth in the cross-sectional area is in a range of about 1 to 5 percent (and may further include, e.g., one or more of copper, nickel, and germanium).

Example 18 provides the microelectronic assembly of any one of examples 15-16, where: a percentage of indium in the cross-sectional area is in a range of about 1 to 2 percent.

Example 19 provides the microelectronic assembly of any one of examples 15-16, where: a percentage of bismuth in the cross-sectional area is in a range of about 30 to 40 percent.

Example 20 provides the microelectronic assembly of any one of examples 15-16, where: a percentage of indium in the cross-sectional area is in a range of about 15 to 25 percent.

Example 21 provides the microelectronic assembly of any one of examples 15-20 where the first die is an embedded bridge die.

Example 22 provides the microelectronic assembly of any one of examples 15-21, where the substrate and/or the second die are examples of an apparatus in accordance with any one of examples 1-14.

Example 23 provides the microelectronic assembly of any one of examples 15-22, further including a further substrate below and coupled with the substrate with further interconnects.

Example 24 provides the apparatus or microelectronic assembly according to any one of examples 1-23, where the apparatus or microelectronic assembly includes or is a part of a CPU.

Example 25 provides the apparatus or microelectronic assembly according to any one of examples 1-24, where the apparatus or microelectronic assembly includes or is a part of a memory device.

Example 26 provides the apparatus or microelectronic assembly according to any one of examples 1-25, where the apparatus or microelectronic assembly includes or is a part of a logic circuit.

Example 27 provides the apparatus or microelectronic assembly according to any one of examples 1-26, where the apparatus or microelectronic assembly includes or is a part of input/output circuitry.

Example 28 provides the apparatus or microelectronic assembly according to any one of examples 1-27, where the apparatus or microelectronic assembly includes or is a part of a field programmable gate array transceiver.

Example 29 provides the apparatus or microelectronic assembly according to any one of examples 1-28, where the apparatus or microelectronic assembly includes or is a part of a field programmable gate array logic.

Example 30 provides the apparatus or microelectronic assembly according to any one of examples 1-29, where the apparatus or microelectronic assembly includes or is a part of a power delivery circuitry.

Example 31 provides an IC package that includes a microelectronic assembly according to any one of examples 1-30.

Example 32 provides the IC package according to example 31, further including a further IC component coupled to the apparatus or microelectronic assembly.

Example 33 provides the IC package according to example 32, where the further IC component includes a package substrate.

Example 34 provides the IC package according to example 32, where the further IC component includes an interposer.

Example 35 provides the IC package according to example 32, where the further IC component includes a further assembly or die.

Example 36 provides a computing device that includes a carrier substrate and an assembly coupled to the carrier substrate, where the assembly is an assembly according to any one of examples 1-30, or the assembly is included in the IC package according to any one of examples 31-35.

Example 37 provides the computing device according to example 36, where the computing device is a wearable or handheld computing device.

Example 38 provides the computing device according to examples 36 or 37, where the computing device further includes one or more communication chips.

Example 39 provides the computing device according to any one of examples 36-38, where the computing device further includes an antenna.

Example 40 provides the computing device according to any one of examples 36-39, where the carrier substrate is a motherboard.

Example 41 provides a method of fabricating a microelectronic assembly, the method including providing a microelectronic component, where: the microelectronic component is a substrate or a die, and a face of the microelectronic component includes a plurality of conductive contacts; providing a solder bump on one of the plurality of conductive contacts, where the solder bump includes a first solder material; providing a solder cap on the solder bump, where the solder cap includes a second solder material having a lower melting point than the first solder material; and providing the microelectronic component with the solder bump and solder cap pre-reflow for bonding with a further microelectronic component.

Example 42 provides the method of example 41, further including providing an individual solder bump on each of the plurality of conductive contacts, and providing an individual solder cap on the individual solder bump on only some of the plurality of conductive contacts.

Example 43 provides the method of example 42, where providing the individual solder cap includes providing the individual solder cap on the individual solder bump on conductive contacts proximate to edges of the microelectronic component.

Example 44 provides the method of example 42, where providing the individual solder cap includes providing the individual solder cap on the individual solder bump on conductive contacts proximate to corners of the microelectronic component.

Example 45 provides the method of any one of examples 41-44, where: the second solder material includes a eutectic solder material including tin and one or more of indium and bismuth.

Example 46 provides a method of fabricating a microelectronic assembly, the method including providing a first microelectronic component and a second microelectronic component, where: one of the first microelectronic component and the second microelectronic is a die and another of the first microelectronic component and the second microelectronic component is a substrate, and the first microelectronic component includes a first plurality of solder bumps including a first solder material, the second microelectronic component includes a second plurality of solder bumps including the first solder material, and at least one solder bump of the first plurality or the second plurality includes a pre-reflow solder bump of the first solder material and a pre-reflow solder cap of a second solder material having a lower melting point than the first solder material; and bonding the first plurality of solder bumps with the second plurality of solder bumps.

Example 47 provides the method of example 46, where: the at least one solder bump including a pre-reflow solder cap is proximate to an edge of the first microelectronic component or the second microelectronic component.

Example 48 provides the method according to any one of examples 41-47, where the microelectronic assembly is a microelectronic assembly according to any one of the preceding examples.

Example 49 provides a process of making a microelectronic assembly according to the method of any one of examples 41-48.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A microelectronic assembly, comprising:
a substrate;
an integrated circuit (IC) die over and bonded with the substrate; and
a plurality of conductive interconnects between and coupled with the substrate and the IC die, wherein:
a conductive interconnect of the plurality of conductive interconnects comprises a first solder material,
in a cross-section of the conductive interconnect, the conductive interconnect comprises regions of a second solder material in the first solder material, and
the second solder material has a different material composition than the first solder material.

2. The microelectronic assembly of claim 1, wherein:
the second solder material comprises one or more of indium and bismuth.

3. The microelectronic assembly of claim 2, wherein:
indium and bismuth are substantially absent from the first solder material.

4. The microelectronic assembly of claim 2, wherein:
a percentage of bismuth or indium in a cross-sectional area of the conductive interconnect is in a range of about 1 to 40 percent.

5. The microelectronic assembly of claim 1, wherein:
the first solder material has a first melting point range, and
the second solder material has a second melting point that is lower than the first melting point range.

6. The microelectronic assembly of claim 1, wherein:
the regions comprise eutectic low-temperature solder phase.

7. The microelectronic assembly of claim 1, wherein:
the substrate comprises an embedded bridge die, and
the conductive interconnect is between and coupled with the embedded bridge die and the IC die.

8. The microelectronic assembly of claim 1, wherein:
the conductive interconnect is a first conductive interconnect, and
a second conductive interconnect adjacent to the first conductive interconnect comprises the first solder material and lacks the second solder material.

9. The microelectronic assembly of claim 8, wherein:
the first conductive interconnect is closer to an edge of the IC die than the second conductive interconnect.

10. The microelectronic assembly of claim 1, wherein:
a pitch of the plurality of conductive interconnects is smaller than or equal to about 35 microns.

11. An apparatus, comprising:
a microelectronic component;
a solder bump on a face of the microelectronic component, wherein the solder bump comprises a first pre-reflow portion of a first solder material; and
a solder cap on the solder bump, wherein:
the solder cap comprises a second pre-reflow portion of a second solder material,
the second solder material has a different material composition from the first solder material, and
the second solder material comprises a eutectic solder material comprising tin and one or more of bismuth and indium.

12. The apparatus of claim 11, wherein the solder bump is a first solder bump, the solder cap is a first solder cap, and wherein the apparatus further comprises:
a second solder bump coplanar with the first solder bump, wherein:
the second solder bump comprises a third pre-reflow portion of the first solder material, and
the second solder bump lacks a second solder cap of the second solder material.

13. The apparatus of claim 12, wherein:
the third pre-reflow portion of the first solder material is coplanar with the first solder bump and the first solder cap.

14. The apparatus of claim 12, wherein:
the first solder bump is closer to a corner of the microelectronic component than the second solder bump.

15. A microelectronic assembly, comprising:
a substrate;
an integrated circuit (IC) die over and bonded with the substrate; and
a plurality of conductive interconnects between and coupled with the substrate and the IC die, wherein:
a conductive interconnect of the plurality of conductive interconnects comprises a first solder material and areas of a second solder material in the first solder material,
the second solder material comprises one or both of indium and bismuth, and
a percentage of the second solder material in a cross-sectional area of the conductive interconnect is in a range of about 1 to 40 percent.

16. The microelectronic assembly of claim 15, wherein:
the substrate comprises an embedded bridge die, and the plurality of conductive interconnects are between the embedded bridge die and the IC die.

17. The microelectronic assembly of claim 15, wherein:
the percentage of bismuth in the cross-sectional area is in a range of about 1 to 5 percent.

18. The microelectronic assembly of claim 15, wherein:
the percentage of indium in the cross-sectional area is in a range of about 1 to 2 percent.

19. The microelectronic assembly of claim 15, wherein:
the percentage of bismuth in the cross-sectional area is in a range of about 30 to 40 percent.

20. The microelectronic assembly of claim 15, wherein:
the percentage of indium in the cross-sectional area is in a range of about 15 to 25 percent.
